(19) United States
(12) Patent Application Publication
(10) Pub. No.: US 2025/0081601 A1
(43) Pub. Date: Mar. 6, 2025

(54) SEMICONDUCTOR DEVICE

(71) Applicant: Socionext Inc., Kanagawa (JP)

(72) Inventor: Kazuo TODA, Yokohama (JP)

(21) Appl. No.: 18/821,374

(22) Filed: Aug. 30, 2024

(30) Foreign Application Priority Data
Sep. 5, 2023 (JP) 2023-143839

(51) Int. Cl. H01L 27/088; H01L 23/528; H01L 27/02; H01L 29/66

(52) U.S. Cl. CPC H10D 84/834; H01L 23/5283; H10D 64/017; H10D 89/10

(57) ABSTRACT

A semiconductor device includes a first fin and a second fin, the first fin and the second fin being formed on a substrate and extending in a first direction in a plan view; a first circuit and a second circuit, the first circuit and the second circuit being formed in the first fin; a first tap cell formed in the second fin; and a first dummy gate disposed between the first circuit and the second circuit, disposed on the first fin and the second fin, and extending in a second direction different from the first direction in the plan view. A region located below the first dummy gate in the first fin is electrically connected to the first dummy gate via the second fin forming the first tap cell.

### CROSS-REFERENCE TO RELATED APPLICATIONS

This application is based on and claims priority to Japanese Patent Application No. 2023-143839, filed on Sep. 5, 2023, the entire contents of which are incorporated herein by reference.

### BACKGROUND OF THE INVENTION

### 1. Field of the Invention

The present disclosure relates to a semiconductor device.

### 2. Description of the Related Art

In semiconductor devices, dummy transistors may be disposed between a plurality of transistors provided in fins so as to electrically isolate transistors on both sides of each of the dummy transistors. Such a semiconductor device is provided with a tap cell for supplying a power supply potential to a substrate that is a well region of a transistor.

### RELATED-ART DOCUMENTS

### Patent Documents

Patent Document 1: U.S. Pat. No. 11,562,994
Patent Document 2: U.S. Pat. No. 11,257,826
Patent Document 3: U.S. Pat. No. 10,236,302

### SUMMARY OF THE INVENTION

According to one aspect of the present disclosure, a semiconductor device includes a first fin and a second fin, the first fin and the second fin being formed on a substrate and extending in a first direction in a plan view; a first circuit and a second circuit, the first circuit and the second circuit being formed in the first fin; a first tap cell formed in the second fin; and a first dummy gate disposed between the first circuit and the second circuit, disposed on the first fin and the second fin, and extending in a second direction different from the first direction in the plan view. A region located below the first dummy gate in the first fin is electrically connected to the first dummy gate via the second fin forming the first tap cell.

### BRIEF DESCRIPTION OF THE DRAWINGS

Other objects and further features of the present invention will be apparent from the following detailed description when read in conjunction with the accompanying drawings, in which:

FIG. 1 is a diagram illustrating an example of a layout of a semiconductor device according to a first embodiment;

FIG. 2 is a plan view illustrating an overview of circuits disposed in a core circuit region of FIG. 1;

FIG. 3 is a diagram illustrating an example of a layout of circuits according to a second embodiment, disposed in the core circuit region of FIG. 1;

FIG. 4 is a cross-sectional view illustrating a cross section along Y1-Y1′ of FIG. 3;

FIG. 5 is cross-sectional views illustrating illustrates a cross section along line X1-X1′ of FIG. 3 and a cross section along line X2-X2′ of FIG. 3;

FIG. 6 is a circuit diagram illustrating an example of a circuit formed by elements included in the layout of FIG. 3; and

FIG. 7 is a plan view illustrating an example of circuits according to a third embodiment, disposed in the core circuit region of FIG. 1.

### DESCRIPTION OF THE EMBODIMENTS

As finer microfabrication of semiconductor devices progresses, in order to electrically connect a dummy gate and a substrate in a dummy transistor, it is necessary to provide new wiring and the like for connecting the dummy gate and the substrate, for example. Providing such new wiring and the like may result in an increase in the circuit area.

According to an aspect of the present disclosure, it is desirable to electrically connect a dummy gate of a dummy transistor and a substrate without increasing the circuit area.

Embodiments will be described below with reference to the accompanying drawings. In the following, a symbol indicating a signal is also used as a symbol indicating a signal line or a signal terminal. A symbol indicating a power supply potential is also used as a symbol indicating a power supply line or a power supply terminal to which a power supply potential is supplied.

### First Embodiment

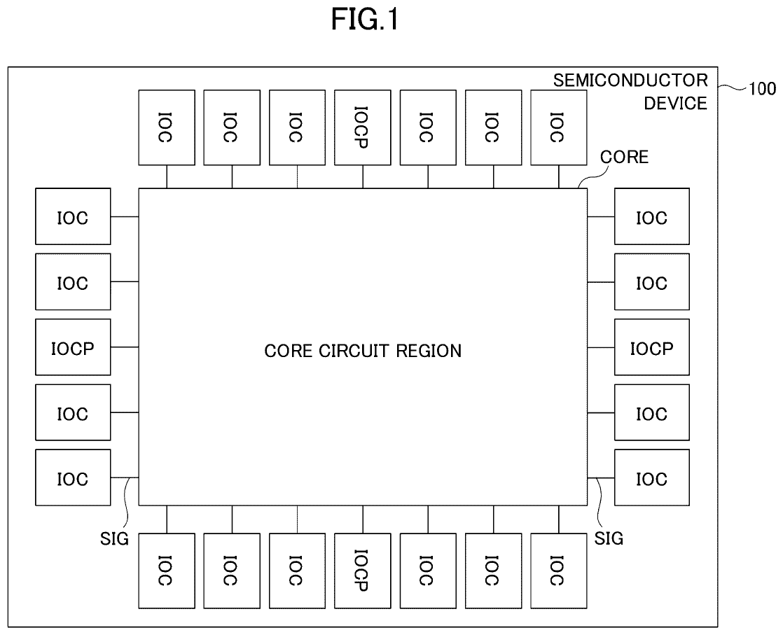

FIG. 1 illustrates an example of a layout of a semiconductor device according to a first embodiment. For example, a semiconductor device 100 illustrated in FIG. 1 may be a system on a chip (SoC), a single field-programmable gate array (FPGA), an application-specific integrated circuit (ASIC), or the like.

The semiconductor device 100 includes a plurality of I/O cells IOC and IOCP, and a core circuit region CORE. An I/O cell IOC is an interface circuit for a signal SIG such as an input signal, an output signal, or an input/output signal. An I/O cell IOCP is an interface circuit for a power supply potential or a ground potential.

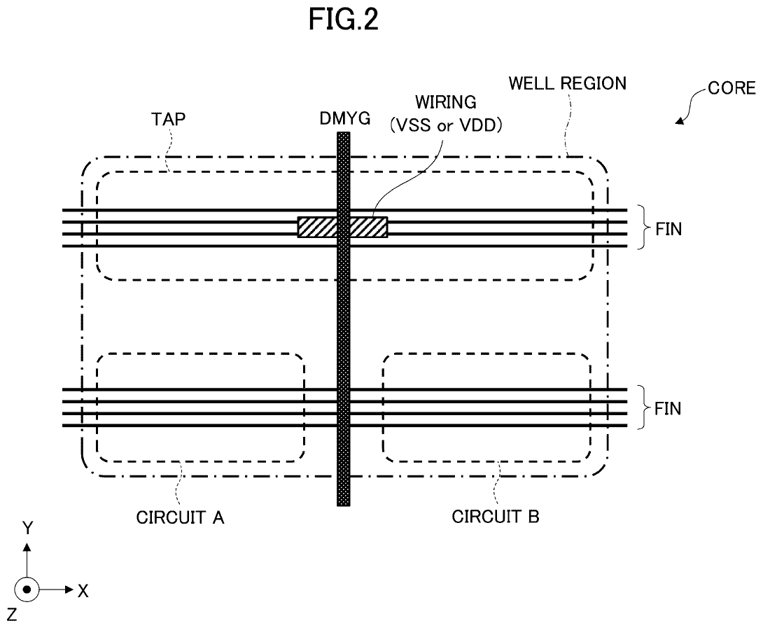

FIG. 2 illustrates an overview of circuits disposed in the core circuit region CORE of FIG. 1. For example, a plurality of fins FIN may be disposed in the core circuit region CORE along the X direction of FIG. 2. Although not particularly limited, four fins FIN are arranged side by side in the Y direction of FIG. 2, a fin group is formed by the four fins FIN. The X direction is an example of a first direction, and the Y direction is an example of a second direction.

A circuit A and a circuit B arranged in the X direction are formed in a region where one of two fin groups illustrated in FIG. 2 is disposed, and a tap cell TAP is formed in a region where the other fin group is disposed. Each fin FIN of the fin group provided in correspondence with the circuit A and the circuit B is an example of a first fin. Each fin FIN of the fin group provided in correspondence with the tap cell TAP is an example of a second fin. The circuit A and the circuit B are an example of a first circuit and an example of a second circuit, respectively. The tap cell TAP is an example of a first tap cell.

A dummy gate electrode DMYG extending in the Y direction is formed between the circuit A and the circuit B. The circuit A and the circuit B are electrically isolated by the dummy gate electrode DMYG. The dummy gate electrode DMYG extends to the region of the tap cell TAP. In each fin FIN, a dummy transistor is formed at the intersection with the dummy gate electrode DMYG. The dummy gate electrode DMYG is hereinafter also simply referred to as a “dummy gate DMYG”. The dummy gate DMYG is an example of a first dummy gate.

Although not illustrated, gate electrodes (gates) are formed along the Y direction in the circuit A and the circuit B. In each of four fins FIN of the circuit A and the circuit B, a channel region of a transistor is formed below a gate electrode (not illustrated) via a gate insulating film, and a source region and a drain region are formed on both sides of the channel region in the X direction.

In the present embodiment, the dummy gate DMYG extends to the tap cell TAP that is adjacent to the circuit A and the circuit B in the Y direction, and the dummy gate DMYG is connected to power supply wiring (a power supply line VDD or a ground line VSS) of the tap cell TAP in the region of the tap cell TAP.

The dummy gate DMYG is electrically connected to a well region (back gate), which is a substrate of a transistor region, through power supply wiring and a via (not illustrated) in the tap cell TAP. The well region is provided in common for the tap cell TAP, the circuit A, and the circuit B. Therefore, in the fins FIN provided in correspondence with the circuit A and the circuit B, channel regions located below the dummy gate DMYG are electrically connected to the dummy gate DMYG via the well region, fins FIN of the tap cell TAP, and wiring connected to the fins FIN of the tap cell TAP.

If the circuit A and the circuit B are PMOS transistors, the well region is an N-type impurity region. In the PMOS transistors, source regions and drain regions of the fins FIN are P-type impurity regions, and channel regions of the fins FIN are N-type impurity regions. Source regions, drain regions, and channel regions of the fins FIN formed in the tap cell TAP, which supplies a power supply potential VDD to the N-type well region, are N-type impurity regions. The dummy gate DMYG electrically connected to the N-type well region is clipped to the power supply potential VDD.

If the circuit A and the circuit B are NMOS transistors, the well region is a P-type impurity region. In the NMOS transistors, source regions and drain regions of the fins FIN are N-type impurity regions, and channel regions of the fins FIN are P-type impurity regions. Source regions, drain regions, the channel regions of the fins FIN formed in the tap cell TAP, which supplies a ground potential VSS to the P-type well region, are P-type impurity regions. The dummy gate DMYG electrically connected to the P-type well region is clipped to the ground potential VSS.

Accordingly, in the first embodiment, by extending the dummy gate DMYG to the tap cell TAP, the dummy gate DMYG can be clipped to a well potential without providing power clip vias, wiring, and the like in the regions where the circuit A and the circuit B are formed. That is, the dummy gate DMYG of the dummy transistor can be electrically connected to the well region, which is the substrate, without increasing the circuit area.

### Second Embodiment

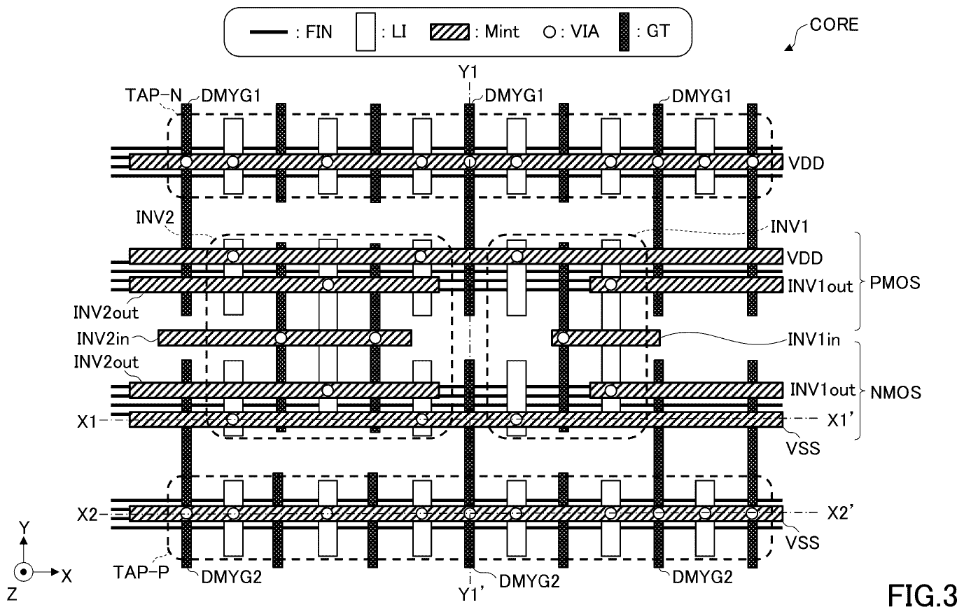

FIG. 3 illustrates an example of a layout of circuits according to a second embodiment, disposed in the core circuit region CORE of FIG. 1. In the example illustrated in FIG. 3, a symbol FIN indicates a fin, a symbol LI indicates a local interconnect, and a symbol Mint indicates wiring formed in a wiring layer above a wiring layer in which the local interconnect LI is formed. A symbol VIA indicates a via connecting the wiring Mint and the local interconnect LI or a gate GT. A symbol GT indicates the gate.

The gate GT includes a dummy gate DMYG1 and a dummy gate DMYG2. The dummy gate DMYG1 is an example of one of the first dummy gate or a second dummy gate, and the dummy gate DMYG2 is an example of the other of the first dummy gate and the second dummy gate. The Fin FIN and the wiring Mint are formed along the X direction of FIG. 2. The local interconnect LI and the gate GT are formed along the Y direction of FIG. 2.

In FIG. 3, four fin groups, each including four fins FIN extending in the X direction, are arranged in the Y direction. The number of the fins FIN included in each of the fin groups is not limited to four, and may be one or more. In the fins FIN, dummy transistors are formed at the intersections with dummy gate electrodes DMYG1 and DMYG2.

On both sides of FIG. 3 in the Y direction, a tap cell TAP-N having an N-type impurity region and a tap cell TAP-P having a P-type impurity region are formed in regions where fin groups are formed. The tap cell TAP-N is an example of one of the first tap cell or a second tap cell, and the tap cell TAP-P is an example of the other of the first tap cell and the second tap cell. Each fin FIN of a fin group provided in correspondence with the tap cell TAP-N is an example of one of the second fin or a fourth fin. Each fin FIN of a fin group provided in correspondence with the tap cell TAP-P is an example of the other of the second fin and the fourth fin.

At the center of FIG. 3 in the Y direction, inverters INV1 and INV2 are arranged side by side in the X direction in regions where two fin groups are formed. The inverter INV1 inverts a logical value of an input signal INVlin supplied to a gate GT via wiring Mint, and outputs an output signal INVlout to wiring Mint via a local interconnect LI. The inverter INV2 inverts a logical value of an input signal INV2in supplied to gates GT via wiring Mint, and outputs an output signal INV2out to wiring Mint via a local interconnect LI.

In each of the inverters INV1 and INV2, a PMOS transistor is formed in a fin group on the tap cell TAP-N side, and an NMOS transistor is formed in a fin group on the tap cell TAP-P side. The PMOS transistor and the NMOS transistor are hereinafter also simply referred to as a PMOS and an NMOS, respectively.

Although not illustrated, a common N-type well region is formed in regions where PMOSs of the inverters INV1 and INV2 are formed and a region where the tap cell TAP-N is formed. In addition, a common P-type well region is formed in regions where NMOSs of the inverters INV1 and INV2 are formed and a region where the tap cell TAP-P is formed.

Each of the PMOS of the inverter INV1, the PMOS of the inverter INV2, the NMOS of the inverter INV1, and the NMOS of the inverter INV2 is an example of any of the first circuit, the second circuit, a third circuit, and a fourth circuit. Each of the fins FIN of the fin group provided in correspondence with the PMOSs of the inverters INV1 and INV2 is an example of one of the first fin or a third fin. Each of the fins FIN of the fin group provided in correspondence with the NMOSs of the inverters INV1 and INV2 is an example of the other of the first fin and the third fin.

A dummy gate electrode DMYG1 and a dummy gate electrode DMYG2 extending in the Y direction are arranged in a line between the inverters INV1 and INV2 arranged in the X direction. The dummy gate electrode DMYG1 is disposed across the four fins FIN of the tap cell TAP-N and the four fins FIN in which the PMOSs are formed. The dummy gate electrode DMYG2 is disposed across the four fins FIN of the tap cell TAP-P and the four fins FIN in which the NMOSs are formed.

The dummy gate electrode DMYG1 is disposed when the PMOSs are separated from each other in the X direction, and the dummy gate electrode DMYG2 is disposed when the NMOSs are separated from each other in the X direction. The dummy gate electrode DMYG1 is hereinafter also referred to as a “dummy gate DMYG1”, and the dummy gate electrode DMYG2 is hereinafter also referred to as a “dummy gate DMYG2”.

In the tap cell TAP-N, wiring Mint (VDD) is connected to dummy gates DMYG1 and local interconnects LI through vias VIA. The wiring Mint (VDD) is an example of first power supply wiring. Similarly, in the tap cell TAP-P, wiring Mint (VSS) is connected to dummy gates DMYG2 and local interconnects LI through vias VIA. The wiring Mint (VSS) is an example of the first power supply wiring.

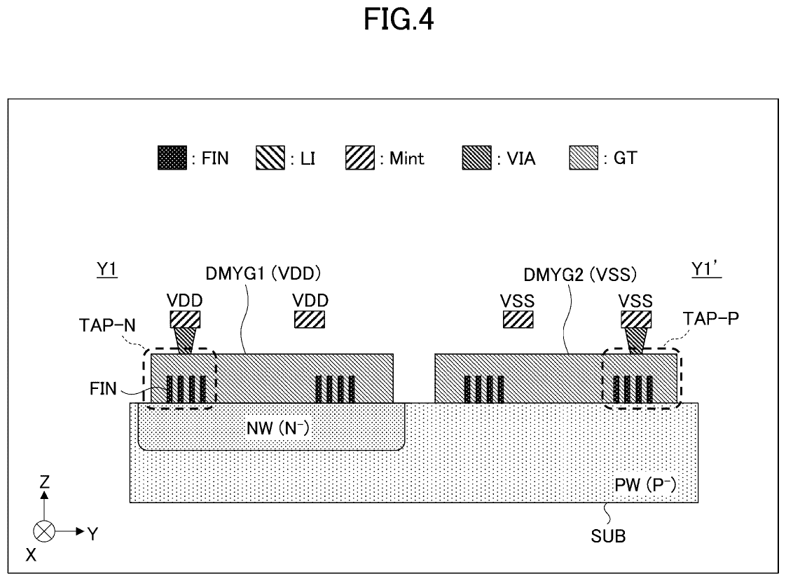

FIG. 4 illustrates a cross section along Y1-Y1′ of FIG. 3. In the cross section of FIG. 4, the dummy gate DMYG1 is formed on two fin groups of the four fin groups formed on a substrate SUB via a gate insulating film (not illustrated), and an N-type well region NW (N⁻) is formed in the substrate SUB below the two fin groups.

The dummy gate DMYG2 is formed on the other two fin groups of the four fin groups formed on the substrate SUB via a gate insulating film, and a P-type well region PW (P⁻) is formed in the substrate SUB below the other two fin groups. A substrate SUB having P-type conductivity may be used, instead of using the P-type well region PW (P⁻). The same applies to other embodiments.

The dummy gate DMYG1 is connected to the power supply line VDD (Mint) through a via VIA in the region of the tap cell TAP-N. The dummy gate DMYG2 is connected to the ground line VSS (Mint) through a via VIA in the region of the tap cell TAP-P.

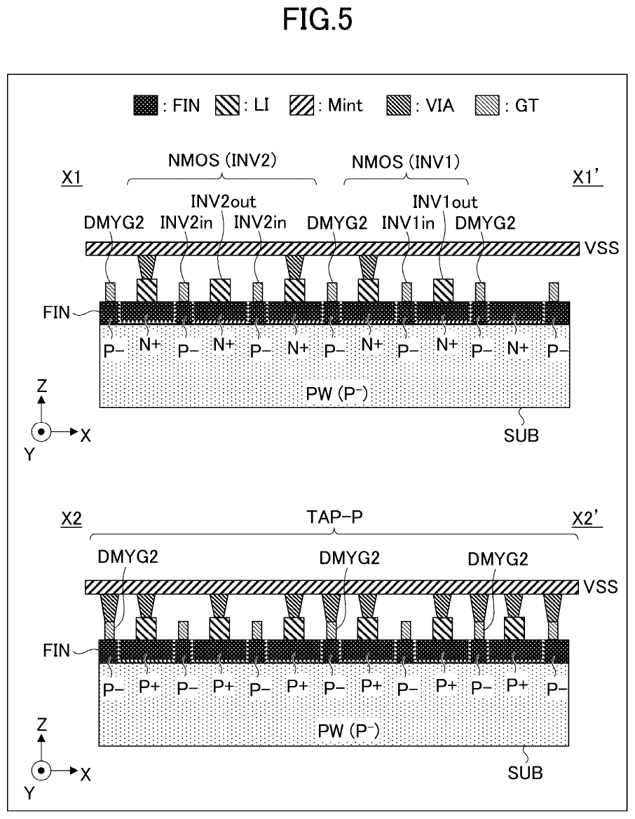

FIG. 5 illustrates a cross section along line X1-X1′ of FIG. 3 and a cross section along line X2-X2′ of FIG. 3. In a fin FIN formed on the substrate SUB (P-type well region PW (P⁻)) of the cross section X1-X1′, p-type impurity regions P⁻ functioning as channel regions of the NMOSs of the inverters INV1 and INV2 are formed below gates GT. Further, in the fin FIN formed on the substrate SUB of the cross section X1-X1′, N-type impurity regions N⁺ functioning as source regions and drain regions of the NMOSs of the inverters INV1 and INV2 are formed. The N-type impurity regions N⁺ is formed on each side of a corresponding P-type impurity region P⁻ in the X direction.

In the regions where the NMOSs are formed, the ground line VSS (Mint) is connected to the source regions (N⁺) of the fin FIN through vias VIA and local interconnects LI. The input signal INV1in or the input signal INV2in is supplied to gate(s) GT other than the dummy gates DMYG2 illustrated in the cross section X1-X1′. In the regions where the NMOSs are formed, the output signal INVlout or the output signal INV2out is output from a drain region (N⁺) of the fin FIN.

In a fin FIN formed on the substrate SUB (P-type well region PW (P⁻)) of the cross section X2-X2′, p-type impurity regions P⁻ are formed below gates GT. Further, in the fin FIN formed on the substrate SUB of the cross section X2-X2′, P-type impurity regions P⁺ for supplying a ground potential VSS are formed. The P-type impurity regions P⁺ are formed on each side of a corresponding p-type impurity region P⁻ in the X direction. In the cross section X2-X2, each of the p-type impurity regions P⁻ of the fin FIN is an example of a first region, and each of the P-type impurity regions P⁺ of the fin FIN is an example of a second region.

In the region where the tap cell TAP-P is formed, the ground line VSS (Mint) is connected to the impurity regions P⁺ of the fin FIN through vias VIA and local interconnects LI, and is connected to the dummy gates DMYG2 through vias VIA. Accordingly, the dummy gates DMYG2 can be electrically connected to the substrate SUB (P-type well region PW (P⁻)) via the ground line VSS (Mint), and the dummy gates DMYG2 can be clipped to the ground potential VSS.

Similarly, although a cross section is not illustrated, the dummy gates DMYG1 can be electrically connected to the N-type well region NW (N⁻), which is a substrate (back gate) of the PMOSs, via the power supply line VDD (Mint). Accordingly, the dummy gates DMYG1 can be clipped to a power supply potential VDD.

In the present embodiment, by extending the dummy gates DMYG2 to the tap cell TAP-P, the dummy gates DMYG2 and the substrate SUB (P-type well region PW (P⁻)), which is set to the ground potential VSS, can be connected to each other in the tap cell TAP-P. Therefore, it is not necessary to provide new local interconnects LI, wiring Mint, vias VIA, and the like in order to clip the dummy gates DMYG2 to the ground potential VSS, and thus an increase in the circuit area of the semiconductor device 100 can be suppressed.

Similarly, by extending the dummy gates DMYG1 to the tap cell TAP-N, the dummy gates DMYG1 and the N-type well region NW (N⁻), which is the substrate (back gate) of the PMOSs and set to the power supply potential VDD, can be connected to each other in the tap cell TAP-N. Therefore, it is not necessary to provide new local interconnects LI, wiring Mint, vias VIA, and the like in order to clip the dummy gates DMYG1 to the power supply potential VDD, and thus an increase in the circuit area of the semiconductor device 100 can be suppressed.

Conversely, if the dummy gates DMYG2 are connected to the substrate SUB (P-type well region PW (P⁻)) without the tap cell TAP-P, it would be necessary to provide new local interconnects LI, wiring Mint, vias VIA, and the like, thus resulting in an increase in the circuit area. In addition, if the dummy gates DMYG1 are connected to the N-type well region NW (N⁻) without the tap cell TAP-N, it would be necessary to provide new local interconnects LI, wiring Mint, vias VIA, and the like, thus resulting in an increase in the circuit area.

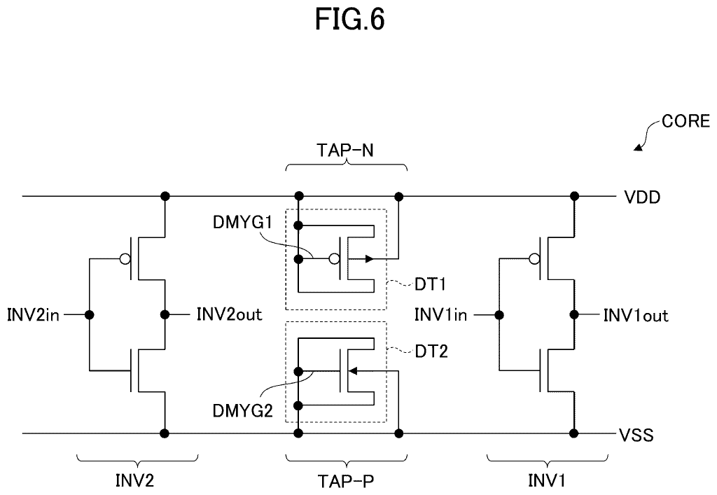

FIG. 6 illustrates an example of a circuit formed by elements included in the layout of FIG. 3. The inverters INV1 and INV2 are provided between the power supply line VDD and the ground line VSS. The tap cell TAP-N is provided with a dummy transistor DT1 in which a dummy gate DMYG1 is connected to a gate. The dummy gate DT1, which is the gate of the dummy transistor DMYG1, and the back gate (N-type well region NW (N⁻)) are connected to the power supply line VDD.

The tap cell TAP-P is provided with a dummy transistor DT2 in which a dummy gate DMYG2 is connected to a gate. The dummy gate DMYG2, which is the gate of the dummy transistor DT2, and the back gate (P-type well region PW (P⁻)) are connected to the ground line VSS.

As illustrated in FIG. 6, a source and a drain of the dummy transistor DT1 may be connected to the power supply line VDD, and a source and a drain of the dummy transistor DT2 may be connected to the ground line VSS. Further, in the example illustrated in FIG. 6, the inverters INV1 and INV2 are provided in the core circuit region CORE; however, any other circuit may be provided in the core circuit region CORE.

As described above, according to the second embodiment, the same effects as the first embodiment can be obtained. For example, by extending the dummy gates DMYG1 to the tap cell TAP-N, the dummy gates DMYG1 can be electrically connected to the N-type well region NW (N⁻), which is the substrate of the PMOSs, without increasing the circuit area. Further, by extending the dummy gates DMYG2 to the tap cell TAP-P, the dummy gates DMYG2 can be electrically connected to the P-type well region PW (P⁻), which is the substrate of the NMOSs, without increasing the circuit area.

### Third Embodiment

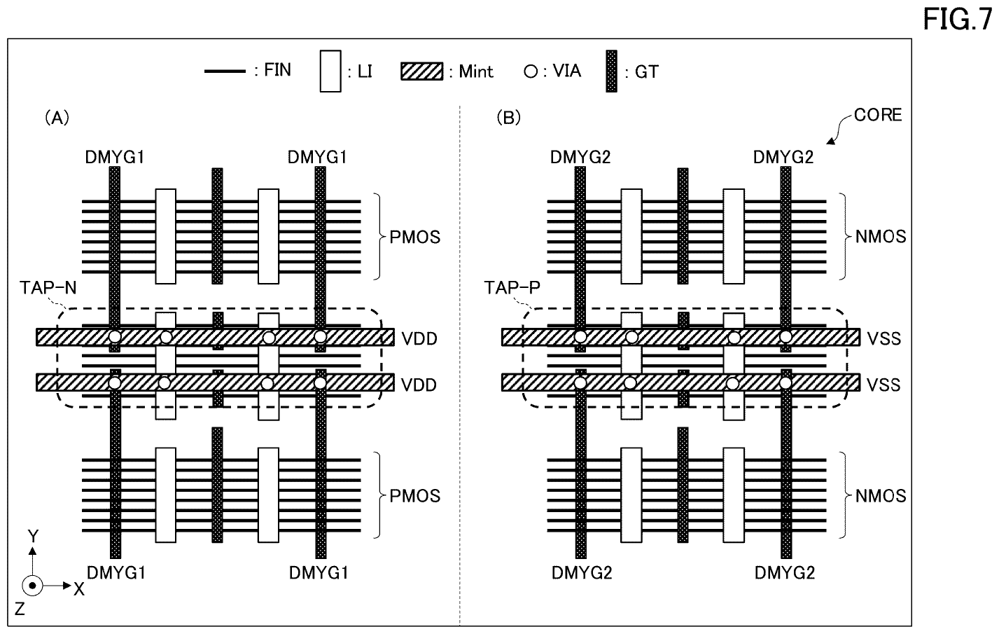

FIG. 7 illustrates an example of circuits according to a third embodiment, disposed in the core circuit region CORE of FIG. 1. Elements the same as those of FIG. 1 are denoted by the same reference numerals, and a detailed description thereof will be omitted. In the example illustrated in FIG. 7, each of fin groups includes eight fins FIN; however, the number of the fins FIN of included in each of the fin groups may be any number other than eight. Further, in FIG. 7, wiring Mint, vias VIA, and the like arranged over fins FIN where PMOSs and NMOSs are formed are not depicted; however, wiring Mint, vias VIA, and the like may be arranged in the same manner as in FIG. 3.

The third embodiment differs from the second embodiment (FIG. 3) in that a dummy gate DMYG1 is divided at its middle in the Y direction in a tap cell TAP-N of a region (A), and a dummy gate DMYG2 is divided at its middle in the Y direction in a tap cell TAP-P of a region (B).

A plurality of dummy gates DMYG1, each divided at its middle, extend to both sides of the tap cell TAP-N in the Y direction, and a plurality of dummy gates DMYG2, each divided at its middle, extend to both sides of the tap cell TAP-P in the Y direction. Note that only the dummy gates DMYG1 in the tap cell TAP-N may be divided, or only the dummy gates DMYG2 in the tap cell TAP-P may be divided.

In FIG. 7, the pictures of the region (A) including the tap cell TAP-N and the region (B) including the tap cell TAP-P are arranged side by side in the X direction; however, the actual regions (A) and (B) are arranged side by side in the Y direction. For example, the region (A) includes, in addition to regions corresponding to the PMOS and the tap cell TAP-N of FIG. 3, a region of a PMOS on the positive Y side of the tap cell TAP-N. The region (B) includes, in addition to regions corresponding to the NMOS and the tap cell TAP-P of FIG. 3, a region of a NMOS on the negative Y side of the tap cell TAP-P.

For example, there are restrictions on the upper limits of the arrangement density and the length of gates GT. As used herein, the arrangement density of the gates GT is the ratio of the area of the gates GT to the area of a predetermined region. By dividing one or both of the dummy gates DMYG1 and DMYG2, the restrictions on the upper limits of the arrangement density and the length of the gates GT can be avoided.

As described above, according to the third embodiment, the same effects as the first embodiment and the second embodiment can be obtained. For example, the dummy gates DMYG1 and DMYG2 extend to the tap cell TAP-N and the tap cell TAP-P, respectively. Accordingly, without increasing the circuit area, the dummy gates DMYG1 can be electrically connected to a substrate of the PMOSS, and the dummy gates DMYG2 can be electrically connected to a substrate of the NMOSs.

Further, in the third embodiment, by dividing one or both of the dummy gates DMYG1 and DMYG2, the restrictions on the upper limits of the arrangement density and the length of the gates GT can be avoided.

According to an embodiment of the present disclosure, a dummy gate of a dummy transistor can be electrically connected to a substrate without increasing the circuit area.

Although the present invention has been described above with reference to the embodiments, the present invention is not limited to the requirements described in the embodiments. These points can be changed without departing from the scope of the present invention, and can be appropriately determined according to the implementation to which the present invention is applied.

What is claimed is:

1. A semiconductor device comprising:
a first fin and a second fin, the first fin and the second fin being formed on a substrate and extending in a first direction in a plan view;
a first circuit and a second circuit, the first circuit and the second circuit being formed in the first fin;
a first tap cell formed in the second fin; and
a first dummy gate disposed between the first circuit and the second circuit, disposed on the first fin and the second fin, and extending in a second direction different from the first direction in the plan view,
wherein a region located below the first dummy gate in the first fin is electrically connected to the first dummy gate via the second fin forming the first tap cell.

2. The semiconductor device according to claim 1, further comprising:
first power supply wiring provided in the first tap cell and electrically connected to the first dummy gate and to the second fin.

3. The semiconductor device according to claim 1, wherein the first fin and the second fin are adjacent to each other in the second direction.

4. The semiconductor device according to claim 1, further comprising:
a third fin and a fourth fin, the third fin and the fourth fin being formed on the substrate and extending in the first direction in the plan view;
a third circuit and a fourth circuit, the third circuit and the fourth circuit being formed in the third fin;
a second tap cell formed in the fourth fin; and
a second dummy gate disposed between the third circuit and the fourth circuit, disposed on the third fin and the fourth fin, and extending in the second direction in the plan view,
wherein a region located below the second dummy gate in the third fin is electrically connected to the second dummy gate via the fourth fin included in the second tap cell.

5. The semiconductor device according to claim 1, wherein
in the second fin, a first region is located below the first dummy gate and a second region is located adjacent to the first region in the first direction, and
the second region is electrically connected to the first dummy gate.

6. The semiconductor device according to claim 5, further comprising:
first power supply wiring provided in the first tap cell and electrically connected to the first dummy gate and to the second fin, wherein
the second region of the second fin is electrically connected to the first power supply wiring.

7. The semiconductor device according to claim 1, wherein the first dummy gate is divided in the first tap cell and extends to one side and another side in the second direction.
